(19) United States
(12) Patent Application Publication
(10) Pub. No.: US 2016/0079924 A1
(43) Pub. Date: Mar. 17, 2016

(54) BIAS CIRCUIT, OPERATIONAL AMPLIFIER, AND DELTA SIGMA TYPE AD CONVERTER

(71) Applicant: Kabushiki Kaisha Toshiba, Tokyo (JP)

(72) Inventors: Yosuke Ogawa, Yokohama Kanagawa (JP); Shigeo Imai, Chiba Chiba (JP); Shinji Nakatsuka, Kamakura Kanagawa (JP)

(21) Appl. No.: 14/645,325

(22) Filed: Mar. 11, 2015

(30) Foreign Application Priority Data
Sep. 11, 2014 (JP) 2014-185620

(51) Int. Cl. H03F 1/02; H03M 3/00; H03F 3/45

(52) U.S. Cl. CPC H03F 1/0205; H03F 3/45076; H03M 3/458; H03M 3/422; H03F 2200/555; H03F 2203/45154; H03F 2203/45171

(57) ABSTRACT

According to one embodiment, there are provided a bias voltage generation circuit that generates a bias voltage in an operational amplifier according to a bias current generated inside, and an adaptive timing control circuit that temporarily increases the bias current at a timing at which a first control signal configured to control an input signal of the operational amplifier changes in level.

### CROSS-REFERENCE TO RELATED APPLICATIONS

This application is based upon and claims the benefit of priority from Japanese Patent Application No. 2014-185620, filed on Sep. 11, 2014; the entire contents of which are incorporated herein by reference.

### FIELD

Embodiments described herein relate generally to a bias circuit, an operational amplifier, and a ΔΣ-type AD converter.

### BACKGROUND

For an operational amplifier, there is the need to increase a bias current to be constantly supplied to the operational amplifier to improve settling characteristics, which leads to an increase in power consumption.

### BRIEF DESCRIPTION OF THE DRAWINGS

FIG. 1 is a block diagram of a bias circuit according to a first embodiment that is applied to an operational amplifier;

FIG. 2 is a schematic block diagram of the bias circuit according to the first embodiment;

FIG. 3 is a schematic circuit diagram of the operational amplifier illustrated in FIG. 1;

FIG. 4 is a timing chart illustrating waveforms at components of the bias circuit according to the first embodiment;

FIG. 5A is a diagram illustrating levels of differential input signals before AC modulation, FIG. 5B is a block diagram illustrating a configuration in which a chopped control signal CHP is used as a control signal CS1 illustrated in FIG. 2, FIG. 5C is a diagram illustrating levels of differential input signals after AC modulation, and FIG. 5D is a diagram illustrating a method for separating an input signal from noise;

FIG. 6 is a diagram illustrating results of simulation of waveforms at the components of the configuration illustrated in FIGS. 5A to 5D;

FIG. 7 is a schematic block diagram illustrating a bias circuit according to a second embodiment;

FIG. 8 is a timing chart illustrating waveforms at components of the bias circuit according to the second embodiment;

FIG. 9 is a schematic block diagram illustrating a bias circuit according to a third embodiment;

FIG. 10 is a timing chart illustrating waveforms at components of the bias circuit according to the third embodiment;

FIG. 11 is a block diagram of a bias circuit that is applied to an operational amplifier according to a fourth embodiment;

FIG. 12 is a schematic block diagram of the operational amplifier according to the fourth embodiment;

FIG. 13 is a timing chart of waveforms at components of the operational amplifier according to the fourth embodiment;

FIG. 14 is a schematic block diagram of a ΔΣ-type AD converter according to a fifth embodiment; and

FIG. 15 is a timing chart of waveforms at components of the ΔΣ-type AD converter according to the fifth embodiment.

### DETAILED DESCRIPTION

In general, according to one embodiment, there are provided a bias voltage generation circuit that generates a bias voltage of an operational amplifier according to a bias current generated inside, and an adaptive timing control circuit that temporarily increases the bias current at a timing at which a first control signal configured to control an input signal of the operational amplifier changes in level.

Exemplary embodiments of a bias circuit, an operational amplifier, and a ΔΣ-type AD converter will be explained below in detail with reference to the accompanying drawings. The present invention is not limited to the following embodiments.

### First Embodiment

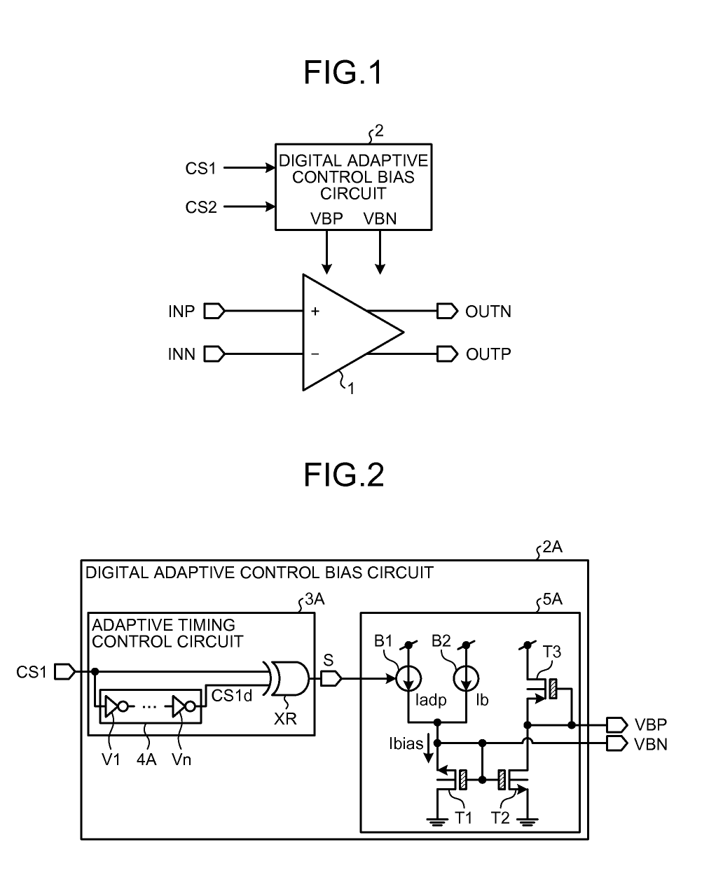

FIG. 1 is a block diagram of a bias circuit according to a first embodiment that is applied to an operational amplifier.

Referring to FIG. 1, differential input signals INP and INN are input into an operational amplifier 1. In addition, the operational amplifier 1 outputs differential output signals OUTN and OUTP according to the differential input signals INP and INN.

Control signals CS1 and CS2 are input into a digital adaptive control bias circuit 2. In addition, the digital adaptive control bias circuit 2 outputs bias voltages VBP and VBN according to the control signals CS1 and CS2. Then, the bias voltages VBP and VBN are supplied to the operational amplifier 1 to set a bias current in the operational amplifier 1. The bias voltage VBP can be applied to a P-channel transistor in the operational amplifier 1. The bias voltage VBN can be applied to an N-channel transistor in the operational amplifier 1.

The digital adaptive control bias circuit 2 can temporarily increase the bias current used inside to generate the bias voltage VBP according to the timing at which the control signal CS1 changes in level (hereinafter, also referred to as adaptive bias control). The timing at which the control signal CS1 changes in level may be at a rising edge or a falling edge of the control signal CS1. In addition, the timing at which the control signal CS1 changes in level can be set according to the timing at which the differential input signals INP and INN change in level. At that time, the control signal CS1 may use a clock for deciding the timing at which the differential input signals INP and INN are sampled.

The digital adaptive control bias circuit 2 can also control the time during which the bias current used inside to generate the bias voltage VBP temporarily increases or the amount of the temporary increase of the bias current according to the control signal CS2. The control signal CS2 can be set according to the potential difference between the differential output signals OUTN and OUTP. Alternatively, the control signal CS2 may be set according to the temperature of the operational amplifier 1, the process, or the power-source voltage.

By temporarily increasing the bias current used to generate the bias voltage VBP according to the timing at which the control signal CS1 changes in level, driving force of the operational amplifier 1 can be increased according to the timing at which the differential output signals OUTN and OUTP change in level. This makes it possible to reduce power consumption as compared to the case of constantly increasing the bias current used to generate the bias voltage VBP, thereby to improve settling characteristics while suppressing increase in power consumption.

FIG. 2 is a schematic block diagram of the bias circuit according to the first embodiment.

Referring to FIG. 2, a digital adaptive control bias circuit 2A is provided as the digital adaptive control bias circuit 2 illustrated in FIG. 1. The digital adaptive control bias circuit 2A includes an adaptive timing control circuit 3A and a bias voltage generation circuit 5A. The adaptive timing control circuit 3A controls a boost current Iadp in a current source B1 according to the timing at which the control signal CS1 changes in level to temporarily increase a bias current Ibias used to generate the bias voltages VBP and VBN. The adaptive timing control circuit 3A includes a delay circuit 4A and an exclusive OR circuit XR. The bias voltage generation circuit 5A includes n (n denotes a positive integer) stages of inverters V1 to Vn. The bias voltage generation circuit 5A generates the bias voltages VBP and VBN of the operational amplifier 1 based on the bias current Ibias. The bias voltage generation circuit 5A includes current sources B1, B2, N-channel transistors T1, T2, and a P-channel transistor T3. The current sources B1 and B2 are connected in parallel to the drain of the N-channel transistor T1. The N-channel transistors T1 and T2 are current mirror-connected. The P-channel transistor T3 is connected in series to the N-channel transistor T2. The N-channel transistor T1 can be used to generate the bias voltage VBN. The P-channel transistor T3 can be used to generate the bias voltage VBP.

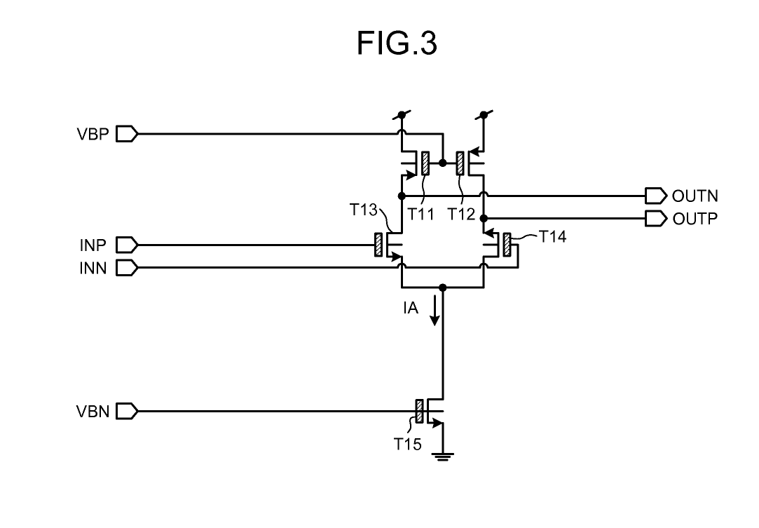

FIG. 3 is a schematic circuit diagram of the operational amplifier illustrated in FIG. 1.

Referring to FIG. 3, the operational amplifier 1 is provided with N-channel transistors T13 to T15 and P-channel transistors T11 and T12. The N-channel transistors T13 and T14 can constitute differential stages in the operational amplifier 1. The P-channel transistors T11 and T12 can set the bias current in the operational amplifier 11 according to the bias voltage VBP. The N-channel transistor T15 can set the bias current in the operational amplifier 1 according to the bias voltage VBN. The P-channel transistor T11 and the N-channel transistor T13 are connected in series to each other. The P-channel transistor T12 and the N-channel transistor T14 are connected in series to each other. The drain of the N-channel transistor T15 is coupled to the source of the N-channel transistor T13 and the drain of the N-channel transistor T14. The bias voltage VBP is applied to the gates of the P-channel transistors T11 and T12. The bias voltage VBN is applied to the gate of the N-channel transistor T15. At that time, a tail current IA flows into the N-channel transistors T13 and T14. The differential input signal INP is applied to the gate of the N-channel transistor T13. The differential input signal INN is applied to the gate of the N-channel transistor T14. The differential output signal OUTN is output from the drain of the N-channel transistor T13. The differential output signal OUTP is output from the source of the N-channel transistor T14.

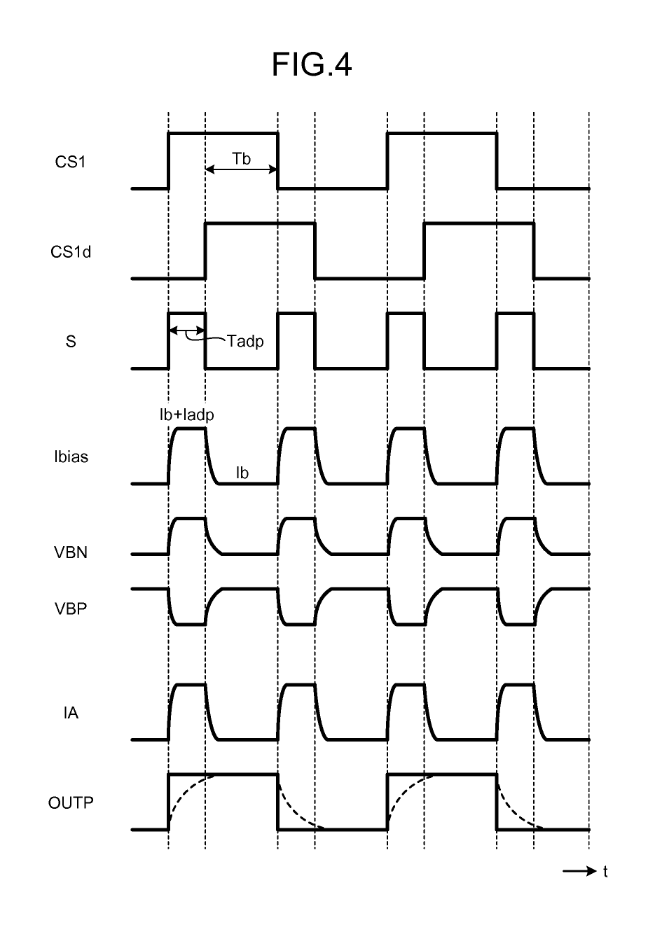

FIG. 4 is a timing chart illustrating waveforms at components of the bias circuit according to the first embodiment.

Referring to FIG. 4, before rising of a pulse signal S, the boost current Iadp is not output and a bias current Ibias is set as bias current Ib. Upon input of the control signal CS1, the control signal CS1 is delayed in the delay circuit 4A to generate a delayed control signal CS1d. Then, at the exclusive OR circuit XR, the logical sum of the control signal CS1 and the delayed control signal CS1d is taken to generate the pulse signal S. The pulse signal S is output to the current source B1. The pulse width of the pulse signal S can be set as Tadp, and the pulse interval of the pulse signal S can be set as Tb.

Then, when the pulse signal S is output to the current source B1, the boost current Iadp is output from the current source B1. Meanwhile, the bias current Ib is constantly output from the current source B2. Then, the boost current Iadp and the bias current Ib join with each other to generate a bias current Ibias. The bias current Ibias is supplied to the N-channel transistor T1. When the bias current Ibias is supplied to the N-channel transistor T1, a bias voltage VBN is generated. At that time, the bias voltage VBN is temporarily increased corresponding to the pulse width Tadp. In addition, when the bias current Ibias is applied to the gates of the N-channel transistors T1 and T2, electric current flows into the N-channel transistor T2. Accordingly, electric current flows into the P-channel transistor T3 according to the bias current Ibias to generate the bias voltage VBP. At that time, the bias voltage VBP is temporarily decreased corresponding to the pulse width Tadp.

Then, the bias current in the operational amplifier 1 is set according to the bias voltages VBP and VBN. At that time, the tail current IA is temporarily increased corresponding to with the pulse width Tadp. When the differential input signals INP and INN are sampled in the operational amplifier 1 according to the control signal CS1 to generate the differential output signals OUTN and OUTP. At that time, when the boost current Iadp is not supplied, the rising and falling edges of the differential output signal OUTP take on blunt waves (OUTP indicated by dotted lines in FIG. 4). Meanwhile, the waves of the rising and falling edges of the differential output signal OUTP can be sharpened (OUTP indicated by solid lines in FIG. 4) by supplying the boost current Iadp to improve settling characteristics. In addition, power consumption can be reduced by shortening pulse width Tadp of the pulse signal S. To ensure compatibility between the improvement of settling characteristics and the reduction of power consumption, the pulse width Tadp of the pulse signal S is set to be the time until the differential output signal OUTP rises or falls without supply of the boost current Iadp.

In addition, to realize adaptive bias control, small-scale digital circuits such as the delay circuit 4A and the exclusive OR circuit XR are added to suppress an increase in layout area and eliminate the need for a complicated circuit design.

The foregoing descriptions are given as to a configuration in which the exclusive OR circuit XR is provided in the adaptive timing control circuit 3A to apply the process for increasing the bias current Ibias to both edges of the control signal CS1. Alternatively, when the process for increasing the bias current Ibias is to be applied to one edge of the control signal CS1, a logical AND circuit may be provided instead of the exclusive OR circuit XR.

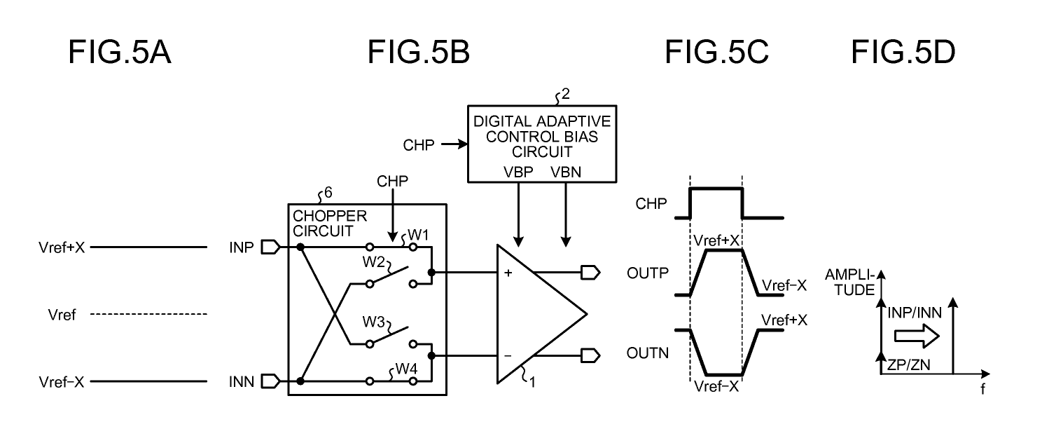

FIG. 5A is a diagram illustrating levels of differential input signals before AC modulation, FIG. 5B is a block diagram illustrating a configuration in which a chopped control signal CHP is used as control signal CS1 illustrated in FIG. 2, FIG. 5C is a diagram illustrating levels of differential input signals after AC modulation, and FIG. 5D is a diagram illustrating a method for separating an input signal from noise.

Referring to FIG. 5B, a chopper circuit 6 is coupled to the input stage of the operational amplifier 1. The chopper circuit 6 includes switches W1 to W4. The chopped control signal CHP is used as the control signal CS1 for the digital adaptive control bias circuit 2. In addition, the chopper circuit 6 turns on or off the switches W1 to W4 according to the chopped control signal CHP to input to the operational amplifier 1 the differential input signals INP and INN with the alternate switching between positive and negative polarities (chopper correction technique).

Thus, as illustrated in FIG. 5A, the differential input signal INP is given as Vref+X, and the differential input signal INN is given as Vref−X, where Vref denotes the in-phase component of the differential input signals INP and INN, and X denotes the differential component of the differential input signals INP and INN. When the chopped control signal CHP rises, the switches W1 and W4 turn on and the switches W2 and W3 turn off, the differential input signal INP is input into the non-inverting input terminal of the operational amplifier 1, and the differential input signal INN is input into the inverting input terminal of the operational amplifier 1. Meanwhile, when the chopped control signal CHP falls, the switches W1 and W4 turn off and the switches W2 and W3 turn on, the differential input signal INP is input into the inverting input terminal of the operational amplifier 1, and the differential input signal INN is input into the non-inverting input terminal of the operational amplifier 1.

Accordingly, as illustrated in FIG. 5C, the levels of the differential input signals INP and INN alternate between Vref+X and Vref−X according to the chopped control signal CHP. As a result, as illustrated in FIG. 5D, frequency f of the differential input signals INP and INN is shifted to the higher side to separate the signal components of the differential input signals INP and INN from noise components ZP and ZN of the differential input signals INP and INN.

By using the chopper correction technique, the positive and negative polarities of the input terminals in the operational amplifier 1 can be alternately switched even if the levels of the differential input signals INP and INN are hardly changed. Accordingly, to enhance the speed of the operational amplifier 1, the operational amplifier 1 needs to be improved in setting characteristics. Thus, by using the chopped control signal CHP as control signal CS1 for the digital adaptive control bias circuit 2, the driving force of the operational amplifier 1 can be increased according to the timing at which the differential output signals OUTN and OUTP change in level. This makes it possible to improve the setting characteristics of the operational amplifier 1 while suppressing an increase in power consumption of the operational amplifier 1.

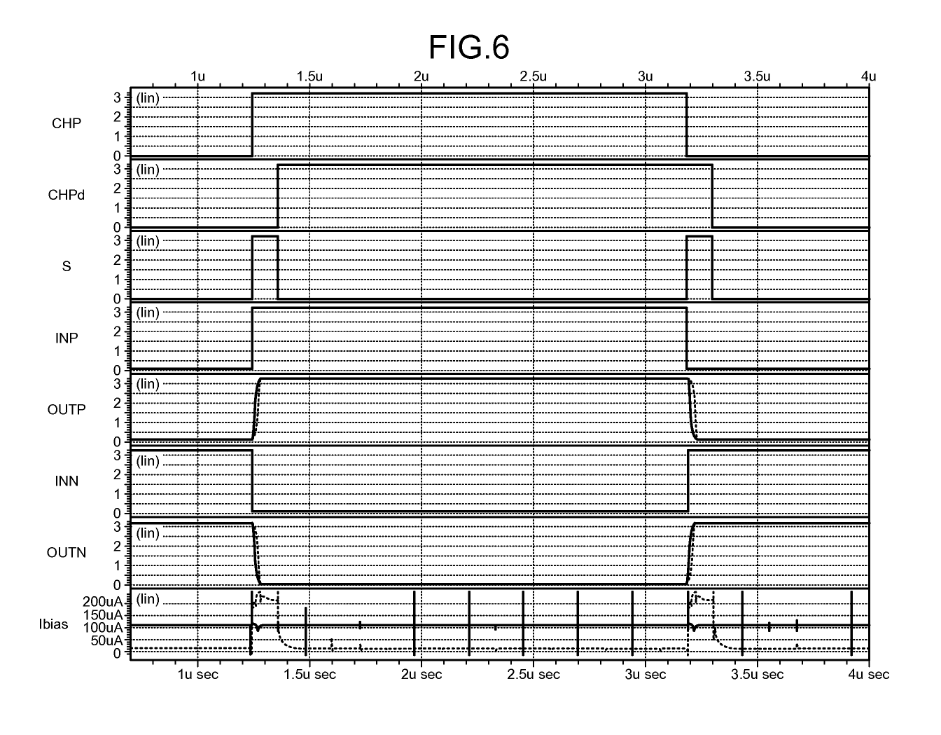

FIG. 6 is a diagram illustrating results of simulation of waveforms at the components of the configuration illustrated in FIGS. 5A to 5D.

Referring to FIG. 6, the chopped control signal CHP is delayed by the delay circuit 4A illustrated in FIG. 2 to generate a delayed chopped control signal CHPd. Then, at the exclusive OR circuit XR, the exclusive logical sum of the chopped control signal CHP and the delayed chopped control signal CHPd is taken to generate the pulse signal S, and the pulse signal S is output to the current source B1. When the pulse signal S is output to the current source B1, the boost current Iadp is output from the current source B1. Then, the boost current Iadp and the bias current Ib join with each other to generate the bias current Ibias, and the bias current Ibias is supplied to the N-channel transistor T1. When the bias current Ibias is supplied to the N-channel transistor T1, the bias voltage VBN is generated. In addition, when the bias current Ibias is applied to the gates of the N-channel transistors T1 and T2, electric current flows into the N-channel transistor T2 and the P-channel transistor T3 according to the bias current Ibias to generate the bias voltage VBP. Then, the bias current in the operational amplifier 1 is set according to the bias voltages VBP and VBN. Then, at the operational amplifier 1, the differential output signals OUTN and OUTP are generated with alternate reverse between the positive and negative polarities of the differential input signals INP and INN according to the rising and falling of the chopped control signal CHP.

### Second Embodiment

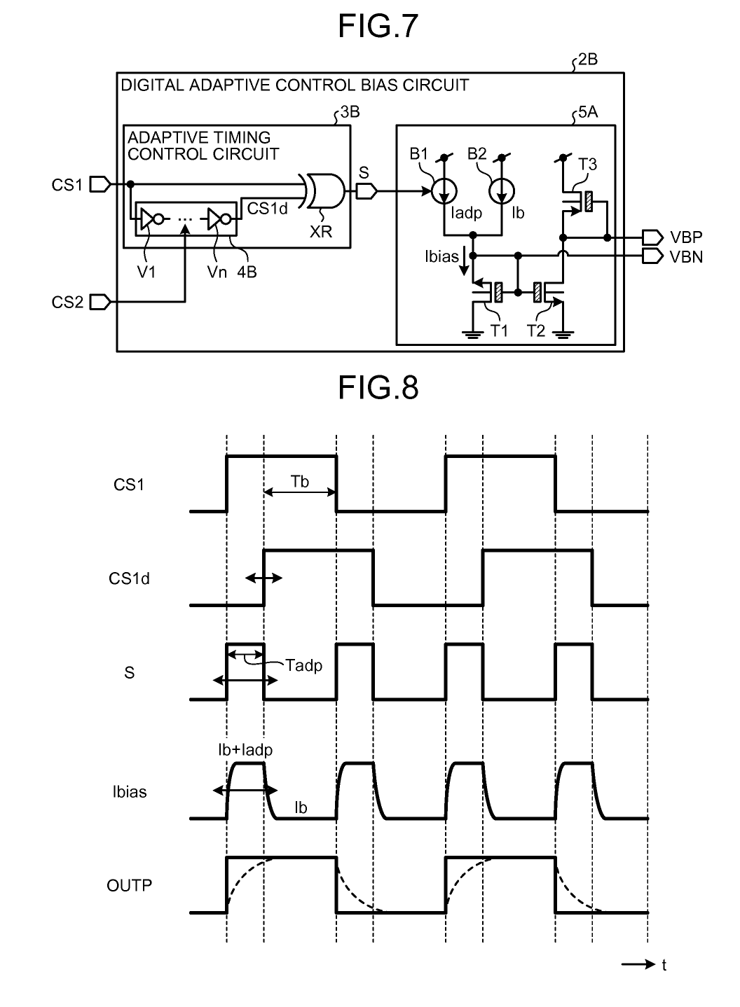

FIG. 7 is a schematic block diagram illustrating a bias circuit according to a second embodiment.

Referring to FIG. 7, a digital adaptive control bias circuit 2B is provided as the digital adaptive control bias circuit 2 illustrated in FIG. 1. The digital adaptive control bias circuit 2B includes an adaptive timing control circuit 3B instead of the adaptive timing control circuit 3A illustrated in FIG. 2. The adaptive timing control circuit 3B includes a delay circuit 4B instead of the delay circuit 4A illustrated in FIG. 2. The delay circuit 4B can change the number of stages of inverters V1 to Vn according to the control signal CS2.

FIG. 8 is a timing chart illustrating waveforms at components of the bias circuit according to the second embodiment.

Referring to FIG. 8, when the number of stages of the inverters V1 to Vn is changed according to the control signal CS2, the timing for rising or falling of the control signal CS1d is changed. Accordingly, the pulse width Tadp of the pulse signal S changes, and thus the time during which the boost current Iadp is supplied changes according to the signal change. This makes a change to the time during which the bias current Ibias is increased.

The control signal CS2 can be set according to the potential difference between the differential output signals OUTN and OUTP, the temperature of the operational amplifier 1, the process, or the power-source voltage. Accordingly, the pulse width Tadp of the pulse signal S can be optimized according to the potential difference between the differential output signals OUTN and OUTP, the temperature of the operational amplifier 1, the process, or the power-source voltage, thereby to minimize an increase in power consumption of the operational amplifier 1.

### Third Embodiment

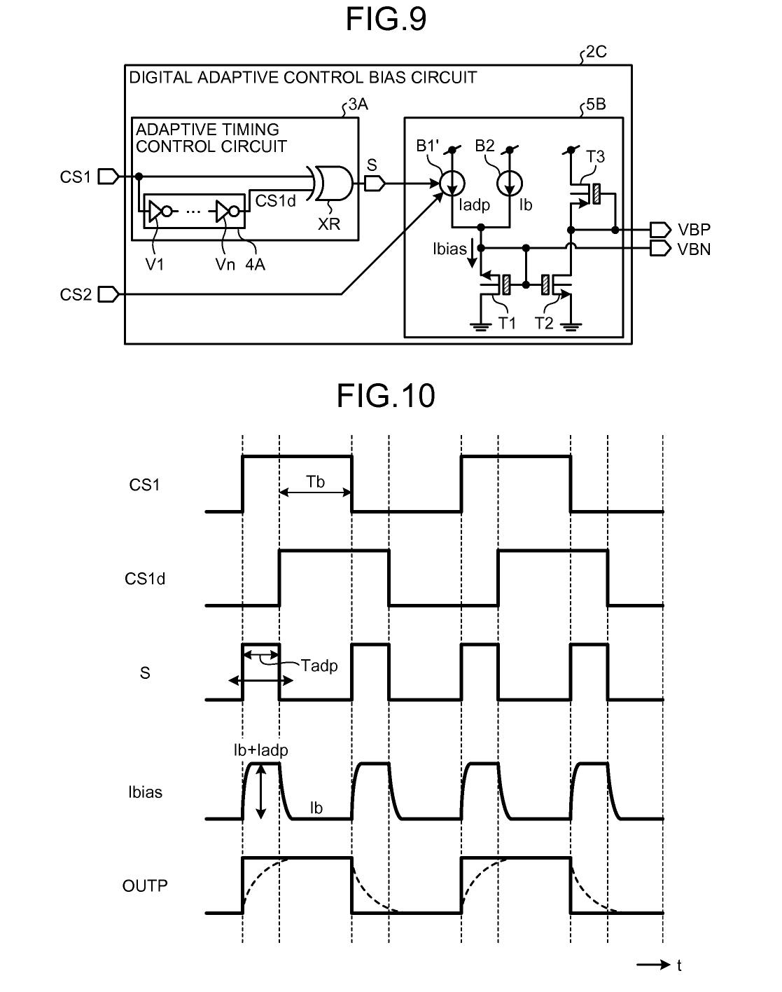

FIG. 9 is a schematic block diagram illustrating a bias circuit according to a third embodiment.

Referring to FIG. 9, a digital adaptive control bias circuit 2C is provided as the digital adaptive control bias circuit 2 illustrated in FIG. 1. The digital adaptive control bias circuit 2C includes a bias voltage generation circuit 5B instead of the bias voltage generation circuit 5A illustrated in FIG. 2. The delay circuit 4B includes a variable current source B1′ instead of the current source B1 illustrated in FIG. 2. The variable current source B1′ can change the boost current Iadp according to the control signal CS2.

FIG. 10 is a timing chart illustrating waveforms at components of the bias circuit according to the third embodiment.

Referring to FIG. 10, when the boost current Iadp is changed according to the control signal CS2, the bias current Ibias is also changed.

The control signal CS2 can be set according to the potential difference between the differential output signals OUTN and OUTP, the temperature of the operational amplifier 11, the process, or the power-source voltage. Accordingly, the increase in the boost current Iadp can be optimized according to the potential difference between the differential output signals OUTN and OUTP, the temperature of the operational amplifier 11, the process, or the power-source voltage, thereby to minimize an increase in power consumption of the operational amplifier 11.

### Fourth Embodiment

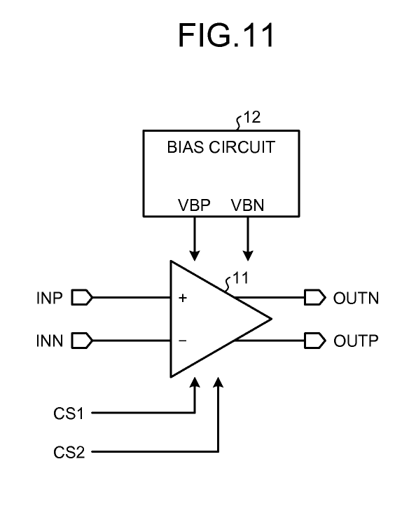

FIG. 11 is a block diagram of a bias circuit that is applied to an operational amplifier according to a fourth embodiment.

Referring to FIG. 11, the differential input signals INP and INN are input into an operational amplifier 11. The differential output signals OUTN and OUTP are output from the operational amplifier 11 according to the differential input signals INP and INN. In addition, the control signals CS1 and CS2 are input into the operational amplifier 11.

The operational amplifier 11 can temporarily increase tail current in the operational amplifier (electric current commonly flowing in the differential stages of the operational amplifier 1) according to the timing at which the control signal CS1 changes in level. The operational amplifier 11 can also control the time during which the tail current in the operational amplifier 11 is temporarily increased or the amount of the increase in the tail current in the operational amplifier 11, according to the control signal CS2.

The bias voltages VBP and VBN are constantly output from the bias circuit 12. The bias voltages VBP and VBN are supplied to the operational amplifier 11 to set the bias current in the operational amplifier 11.

By temporarily increasing the tale current in the operational amplifier 11 according to the timing at which the control signal CS1 changes in level, the driving force of the operational amplifier 11 can be increased according to the timing at which the differential output signals OUTN and OUTP change in level. This makes it possible to reduce power consumption as compared to the case of constantly increasing the tail current in the operational amplifier 11, thereby to improve settling characteristics while suppressing increase in power consumption.

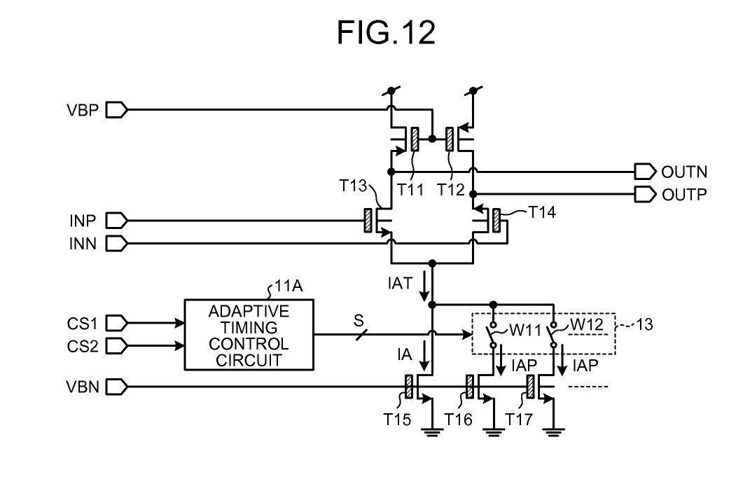

FIG. 12 is a schematic block diagram of the operational amplifier according to the fourth embodiment.

Referring to FIG. 12, the operational amplifier 11 includes an adaptive timing control circuit 11A, a switch circuit 13, N-channel transistors T13 to T17, and P-channel transistors T11 and T12. The switch circuit 13 includes switches W11 and W12. The N-channel transistors T13 and T14 constitute the differential stages in the operational amplifier 11. The P-channel transistors T11 and T12 can set the bias current in the operational amplifier 11 according to the bias voltage VBP. The N-channel transistors T15 to T17 can set the amount of bias in the operational amplifier 11 according to the bias voltage VBN. The P-channel transistor T11 and the N-channel transistor T13 are connected in series. The P-channel transistor T12 and the N-channel transistor T14 are connected in series. The drain of the N-channel transistor T15 is coupled to the source of the N-channel transistor T13 and the drain of the N-channel transistor T14. The drains of the N-channel transistors T16 and T17 are coupled to the source of the N-channel transistor T13 and the drain of the N-channel transistor T14 via the switch circuit 13. The bias voltage VBP is applied to the gates of the P-channel transistors T11 and T12. The bias voltage VBN is applied to the gates of the N-channel transistors T15 to T17. The differential input signal INP is applied to the gate of the N-channel transistor T13. The differential input signal INN is applied to the gate of the N-channel transistor T14. The differential output signal OUTN is output from the drain of the N-channel transistor T13. The differential output signal OUTP is output from the source of the N-channel transistor T14. The adaptive timing control circuit 11A can temporarily increase a tail current IAT in the operational amplifier 11 by turning on or off the switches W11 and W12 according to the timing at which the control signal CS1 changes in level. The operational amplifier 11A can also control the time during which the tail current IAT in the operational amplifier 11 is temporarily increased or the amount of the temporary increase in the tail current IAT in the operational amplifier 11 by controlling the on time of the switches W11 and W12 or the number of the switches to be turned on according to the control signal CS2. The adaptive timing control circuit 11A can be configured in the same manner as the adaptive timing control circuit 3B illustrated in FIG. 7.

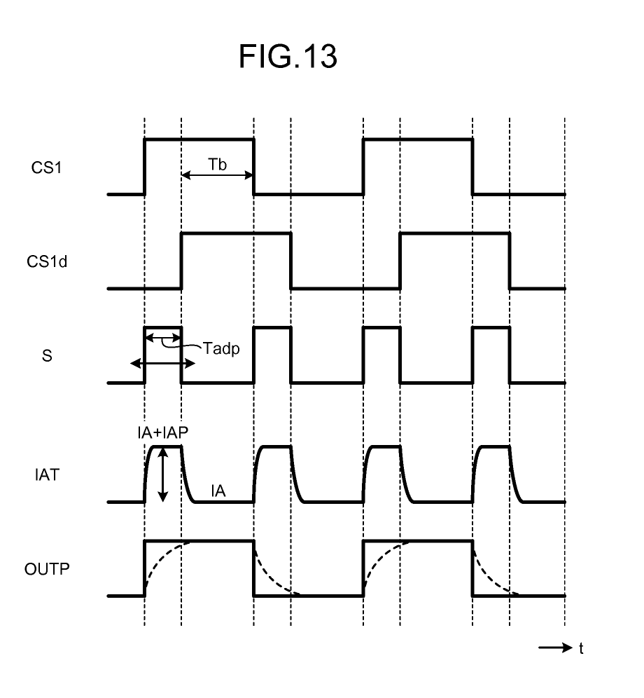

FIG. 13 is a timing chart of waveforms at the components of the operational amplifier according to the fourth embodiment.

Referring to FIG. 13, before the pulse signal S rises, the switches W11 and W12 are turned off and the tail current IAT is set to a tail current IA. Then, upon input of the control signal CS1, the control signal CS1 is delayed at the delay circuit 4A to generate the delayed control signal CS1d. Then, at the exclusive OR circuit XR, the exclusive logical sum of the control signal CS1 and the delayed control signal CS1d is taken to generate the pulse signal S, and the pulse signal S is output to the switch circuit 13. When the pulse signal S is output to the switch circuit 13, the switches W11 and W12 are turned on to flow a boost current IAP to the N-channel transistors T16 and T17. Meanwhile, the tail current IA is constantly flown into the N-channel transistor T15. Then, the boost current IAP and the tail current IA join with each other to generate the tail current IAT. Then, at the operational amplifier 1, the differential input signals INP and INN are sampled according to the control signal CS1 to generate the differential output signals OUTN and OUTP. At that time, when the boost current IAP is not supplied, the rising and falling edges of the differential output signal OUTP take on blunt waves (OUTP indicated by dotted lines in FIG. 13). Meanwhile, the waves of the rising and falling edges of the differential output signal OUTP can be sharpened (OUTP indicated by solid lines in FIG. 13) by supplying the boost current IAP to improve settling characteristics. In addition, power consumption can be reduced by shortening the pulse width Tadp of the pulse signal S. In addition, to realize adaptive bias control, small-scale digital circuits such as the delay circuit 4B and the exclusive OR circuit XR are added to suppress an increase in layout area and eliminate the need for a complicated circuit design.

In addition, by changing the number of the stages of the inverters V1 to Vn according to the control signal CS2, it is possible to change the pulse width Tadp of the pulse signal S and change the time during which the boost current IAP is supplied. Further, by changing the number of the switches W11 and W12 to be turned on according to the control signal CS2, it is possible to change the increase in the boost current IAP.

### Fifth Embodiment

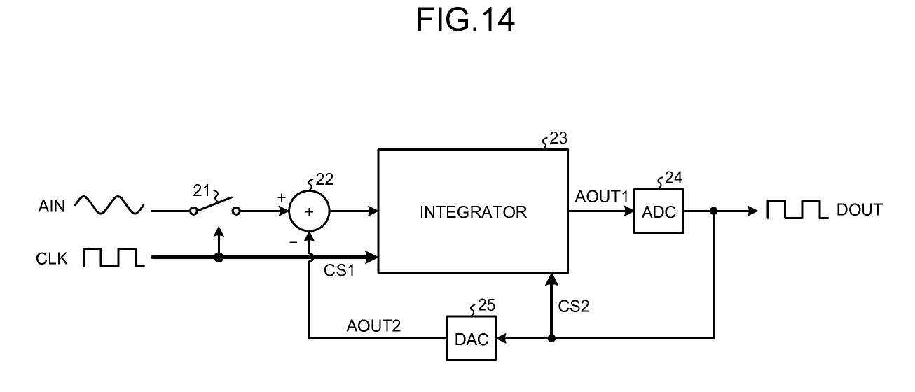

FIG. 14 is a schematic block diagram of a ΔΣ-type AD converter according to a fifth embodiment.

Referring to FIG. 14, the ΔΣ-type AD converter includes a subtractor 22, an integrator 23, an AD converter 24, and a DA converter 25. A sampler 21 is coupled to the input stage of the subtractor 22. The integrator 23 can be equipped with the operational amplifier 1 and the digital adaptive control bias circuit 2 illustrated in FIG. 1. Alternatively, the integrator 23 may be equipped with the operational amplifier 11 and the bias circuit 12 illustrated in FIG. 11. At that time, a clock CLK is input as the control signal CS1 into the integrator 23, and a digital output DOUT is input as the control signal CS2 into the integrator 23. The AD converter 24 can operate as a quantizer. The DA converter 25 can operate as a switch circuit that outputs a reference voltage VF with switching between positive and negative polarities according to the output from the quantizer. The DA converter 25 may be a 1-bit DA converter.

When an analog input AIN is input into the sampler 21, the analog input AIN is sampled according to the clock CLK and input into the subtractor 22. In addition, an analog output AOUT2 is input from the DA converter 25 into the subtractor 22. Then, at the subtractor 22, the analog output AOUT2 is subtracted from the analog input AIN. Then, at the integrator 23, the output from the subtractor 22 is integrated and the integrated result is output as analog output AOUT1. Then, at the AD converter 24, the analog output AOUT1 is quantized to generate a digital output DOUT. Then, at the DA converter 25, when the digital output DOUT is 1, the AOUT2 is set as VF, and when the digital output DOUT is 0, the AOUT2 is set as −VF. At that time, the digital output DOUT becomes a sequence of number 1 or 0. The frequency of occurrence of 1 or 0 in the sequence is set in such a manner that the analog input AIN can be reproduced.

By inputting the clock CLK as the control signal CS1 into the integrator 23, it is possible to increase the driving force of the integrator 23 according to the timing at which the input signal in the integrator 23 changes, and increase the speed of the integrator 23 while suppressing an increase in power consumption.

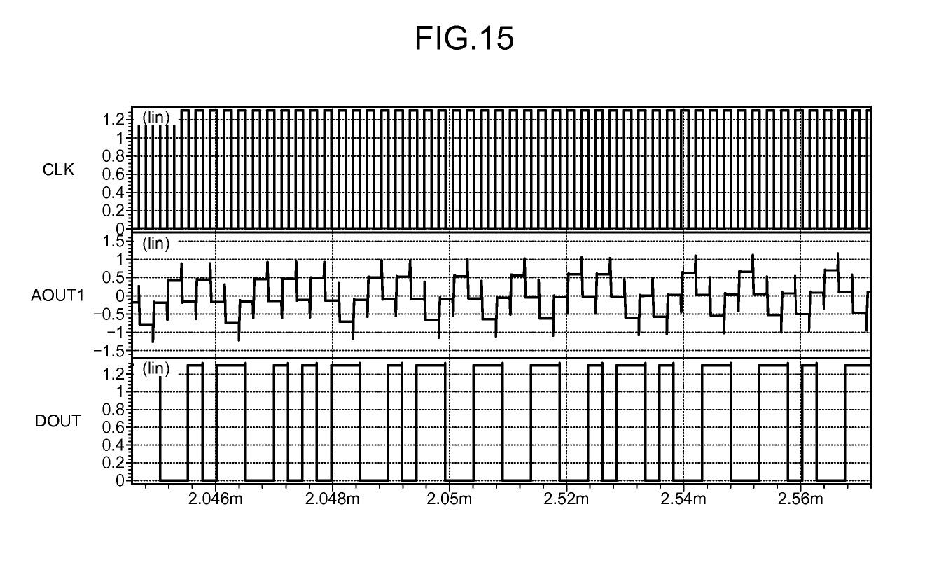

FIG. 15 is a timing chart of waveforms at components of the ΔΣ-type AD converter according to the fifth embodiment.

Referring to FIG. 15, the analog input AIN is sampled according to the clock CLK, and the analog output AOUT2 is subtracted from the analog input AIN. Then, at the integrator 23, the subtracted result is integrated to obtain the analog output AOUT1. Then, at the AD converter 24, the analog output AOUT1 is quantized to generate the digital output DOUT. At that time, the clock CLK can be used as the control signal CS1, and the digital output DOUT can be used as the control signal CS2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A bias circuit, comprising:
a bias voltage generation circuit that generates a bias voltage in an operational amplifier according to a bias current generated inside; and
an adaptive timing control circuit that temporarily increases the bias current at a timing at which a first control signal configured to control an input signal of the operational amplifier changes in level.

2. The bias circuit according to claim 1, wherein the adaptive timing control circuit controls the time during which the bias current is temporarily increased or the amount of the temporary increase in the bias current, according to a second control signal.

3. The bias circuit according to claim 1, wherein the second control signal is set according to an output signal of the operational amplifier.

4. The bias circuit according to claim 1, wherein the timing at which the first control signal changes in level is at a rising edge or falling edge of the first control signal.

5. The bias circuit according to claim 1, wherein the timing at which the first control signal changes in level corresponds to a timing at which the input signal changes in level.

6. The bias circuit according to claim 1, wherein the adaptive timing control circuit includes:
a delay circuit that generates a delayed control signal by delaying the first control signal; and
an exclusive OR circuit that takes the exclusive logical sum of the first control signal and the delayed control signal.

7. The bias circuit according to claim 6, wherein the bias voltage generation circuit includes:
a transistor that outputs the bias voltage;
a first current source that supplies a bias current to the transistor; and
a second current source that supplies a boost current to the transistor according to an output from the exclusive OR circuit,
the first current source and the second current source are connected in parallel and the boost current is added to the bias current.

8. An operational amplifier, comprising:
first and second transistors that set bias currents according to a bias voltage;
third and fourth transistors that constitute a differential stage, differential input signals being applied and the bias currents being supplied to the third and fourth transistors from the first and second transistors;
a fifth transistor that is connected in common to the third and fourth transistors; and
an adaptive timing control circuit that temporarily increases a tail current flowing from the differential stage to the fifth transistor, according to the timing at which a first control signal configured to control the input signal changes in level.

9. The operational amplifier according to claim 8, wherein
the fifth transistor includes a plurality of switch transistors connected in parallel, and
the adaptive timing control circuit controls the number of the switch transistors to be turned on to increase or decrease the tail current.

10. The operational amplifier according to claim 8, wherein the adaptive timing control circuit controls the time during which the tail current is temporarily increased or the amount of the temporary increase in the tail current, according to a second control signal.

11. The operational amplifier according to claim 8, wherein the timing at which the first control signal changes in level is at a rising edge or falling edge of the first control signal.

12. The operational amplifier according to claim 8, wherein the timing at which the first control signal changes in level corresponds to the timing at which an input signal changes in level.

13. The operational amplifier according to claim 8, wherein the adaptive timing control circuit temporarily increases the bias voltage to temporarily increase the tail current.

14. A ΔΣ-type AD converter, comprising:
a subtractor that subtracts an analog output from an analog input;
an integrator that integrates an output from the subtractor;
a quantizer that quantizes an output from the integrator; and
a switch circuit that outputs as the analog output a reference voltage that is switched between positive and negative polarities according to a digital output from the quantizer, wherein
the integrator includes:
an operational amplifier; and
an adaptive timing control circuit that temporarily increases a tail current in the operational amplifier, according to a timing at which a first control signal configured to control the analog input changes in level.

15. The ΔΣ-type AD converter according to claim 14, further comprising:
a sampler configured to sample the analog input is coupled to an input stage of the subtractor, wherein
the first control signal is a clock that decides a timing for sampling the analog input by the sampler.

16. The ΔΣ-type AD converter according to claim 15, wherein the adaptive timing control circuit controls the time during which the tail current is temporarily increased or the amount of the temporary increase in the tail current, according to a second control signal.

17. The ΔΣ-type AD converter according to claim 16, wherein the second control signal is the digital output.

18. The ΔΣ-type AD converter according to claim 14, wherein the operational amplifier includes:
first and second transistors that set bias currents according to a bias voltage;
third and fourth transistors that constitute a differential stage, differential input signals being applied and the bias currents being supplied to the third and fourth transistors from the first and second transistors; and
a fifth transistor that is connected in common to the third and fourth transistors,
the adaptive timing control circuit temporarily increases a driving force of the fifth transistor to temporarily increase the tail current.

19. The ΔΣ-type AD converter according to claim 14, wherein
the integrator includes a bias circuit that supplies a bias voltage to the operational amplifier, and
the adaptive timing control circuit temporarily increases the bias voltage to temporarily increase the tail current.

20. The ΔΣ-type AD converter according to claim 19, wherein
the bias circuit includes a bias voltage generation circuit that generates the bias voltage according to a bias current generated inside, and
the adaptive timing control circuit temporarily increases the bias current in the bias circuit to temporarily increase the bias voltage, temporarily increases the bias voltage to temporarily increase a bias current in the operational amplifier, and temporarily increases the bias current in the operational amplifier to temporarily increase the tail current.
